(19) United States
(12) Patent Application Publication
(10) Pub. No.: US 2024/0279808 A1
(43) Pub. Date: Aug. 22, 2024

(54) GAS SUPPLY SYSTEM

(71) Applicant: SAMSUNG ELECTRONICS CO., LTD., Suwon-si (KR)

(72) Inventors: Minsoo PARK, Suwon-si (KR); Songyi BAEK, Suwon-si (KR); Hyungwoo CHOI, Suwon-si (KR)

(73) Assignee: SAMSUNG ELECTRONICS CO., LTD., Suwon-si (KR)

(21) Appl. No.: 18/419,021

(22) Filed: Jan. 22, 2024

(30) Foreign Application Priority Data
Feb. 21, 2023 (KR) 10-2023-0023026
Jun. 27, 2023 (KR) 10-2023-0082622

(51) Int. Cl. C23C 16/455; C23C 16/44; C23C 16/448; C23C 16/52

(52) U.S. Cl. CPC C23C 16/45561; C23C 16/4405; C23C 16/448; C23C 16/52

(57) ABSTRACT

A gas supply system includes a manifold for supplying gases for processing the substrate to a process chamber; a cleaning gas supply line supplying a cleaning gas to the manifold; a first inert gas supply line supplying a first inert gas to the cleaning gas supply line; a first opening/closing valve opening and closing the cleaning gas supply line; a reaction gas supply line supplying a reaction gas to the manifold; a source gas supply line provided with a vaporizer and supplying the source gas to the manifold; a second inert gas supply line supplying a second inert gas to the manifold and branching out to a carrier gas supply line connected to the vaporizer and a curtain gas supply line bypassing the vaporizer; a second opening/closing valve selectively opening or closing the carrier gas supply line and the curtain gas supply line; and a controller.

### CROSS-REFERENCE TO RELATED APPLICATIONS

This application claims benefit of priority to Korean Patent Application No. 10-2023-0023026, filed on Feb. 21, 2023, and Korean Patent Application No. 10-2023-0082622, filed on Jun. 27, 2023, in the Korean Intellectual Property Office, the disclosures of which are incorporated herein by reference in their entireties.

### BACKGROUND

Embodiments of the present disclosure relate to a gas supply system.

Cleaning gases used in a cleaning process, as well as process gases used in substrate processing, are supplied to a process chamber. Some of the gases used for substrate processing and chamber cleaning may react with each other to produce by-products and contaminate a manifold and the process chamber.

### SUMMARY

According to embodiments of the present disclosure, a gas supply system is provided in which occurrence of a by-product is prevented.

According to embodiments of the present disclosure, a gas supply system is provided. The gas supply system includes: a process chamber configured to receive a substrate; a manifold configured to supply gases for processing the substrate to the process chamber; a cleaning gas supply line configured to supply a cleaning gas provided from a cleaning gas source to the manifold; a first inert gas supply line configured to supply a first inert gas provided from a first inert gas source to the cleaning gas supply line; a first opening/closing valve in the cleaning gas supply line and configured to open and close the cleaning gas supply line; a reaction gas supply line configured to supply a reaction gas provided from a reaction gas source to the manifold; a source gas supply line configured to supply a source gas to the manifold; a vaporizer that is in the source gas supply line and configured to vaporize a source material provided from a source gas source into the source gas; a second inert gas supply line configured to supply a second inert gas provided from a second inert gas source to the manifold, the second inert gas supply line branching out to a carrier gas supply line that is connected to the vaporizer and a curtain gas supply line that bypasses the vaporizer; a second opening/closing valve that is at a branch point of the second inert gas supply line and is configured to selectively open or close the carrier gas supply line and the curtain gas supply line; and a controller configured to simultaneously open or close the cleaning gas supply line and the curtain gas supply line by interlocking the first opening/closing valve and the second opening/closing valve.

According to embodiments of the present disclosure, a gas supply system is provided. The gas supply system includes: a process chamber configured to receive a substrate; a manifold configured to supply gases for processing the substrate to the process chamber; a cleaning gas supply line configured to supply a cleaning gas provided from a cleaning gas source to the manifold; a remote plasma source (RPS) in the cleaning gas supply line and configured to convert the cleaning gas into plasma; a reaction gas supply line configured to supply a reaction gas provided from a reaction gas source to the manifold; a source gas supply line configured to supply a source gas to the manifold; a vaporizer in the source gas supply line and configured to vaporize a source material provided from a source gas source into the source gas; an inert gas supply line configured to supply an inert gas provided from an inert gas source to the manifold; a carrier gas supply line branching off from the inert gas supply line and connected to the vaporizer so that the inert gas is provided to the manifold via the vaporizer; a curtain gas supply line branching off from the inert gas supply line and connected to the reaction gas supply line, the source gas supply line, or the manifold so that the inert gas bypasses the vaporizer to be provided to the manifold; and a controller configured to open and close the cleaning gas supply line, the reaction gas supply line, the source gas supply line, the carrier gas supply line, and the curtain gas supply line.

According to embodiments of the present disclosure, a gas supply system is provided. The gas supply system includes: a manifold configured to supply gases for processing a substrate to a process chamber; a cleaning gas supply line configured to supply a cleaning gas provided from a cleaning gas source to the manifold; a remote plasma source (RPS) in the cleaning gas supply line and configured to convert the cleaning gas into plasma; a reaction gas supply line configured to supply a reaction gas provided from a reaction gas source to the manifold; a source gas supply line connected to the reaction gas supply line so that a source gas is supplied to the manifold through the reaction gas supply line; a vaporizer in the source gas supply line and configured to vaporize a source material provided from a source gas source into the source gas; an inert gas supply line branching out to a carrier gas supply line connected to the vaporizer so that an inert gas provided from an inert gas source joins the source gas via the vaporizer, and a curtain gas supply line connected to the reaction gas supply line so that the inert gas bypasses the vaporizer to be provided to the manifold; and a controller configured to, when the cleaning gas supply line is opened, open the curtain gas supply line and close the carrier gas supply line.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1A, 1B, 1C, 1D, and 1E are diagrams schematically illustrating gas supply systems according to embodiments of the present disclosure;

FIG. 2A is a diagram schematically illustrating a gas supply system according to a comparative example;

FIGS. 2B and 2C are views illustrating a process in which a by-product occurs due to leakage of a source material;

FIG. 2D is a graph illustrating the amount of leakage of a source material and the amount of generation of a by-product in a cleaning process.

FIG. 3 is a diagram illustrating a gas supply system according to an embodiment of the present disclosure;

FIG. 4 is a diagram illustrating a gas supply system in which a carrier gas supply line is opened;

FIG. 5 is a diagram illustrating a gas supply system in which a curtain gas supply line is opened;

FIG. 6 is a graph illustrating a particle reduction effect in a process chamber after applying a gas supply system according to an embodiment of the present disclosure; and

FIG. 7 is a graph illustrating a yield improvement effect after applying a gas supply system according to an embodiment of the present disclosure.

### DETAILED DESCRIPTION

Hereinafter, non-limiting example embodiments of the present disclosure will be described with reference to the accompanying drawings.

It will be understood that when an element is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements present.

Hereinafter, ordinal numbers, such as “first,” “second,” and “third” may be used as labels of specific elements, steps, directions, and the like to distinguish various elements, steps, and directions from each other. Terms not described using “first,” “second,” etc. In the specification may still be referred to as “first” or “second” in the claims. Also, a term referenced by a particular ordinal number (e.g., “first” in a particular claim) may be recited elsewhere by a different ordinal number (e.g., “second” in the specification or another claim).

Unless otherwise specified, in this specification, terms, such as “upper,” “top,” “lower,” “lower,” and “side” are based on the drawings, and the direction in which the components are arranged may vary depending on the direction in which components are arranged, unless otherwise specified.

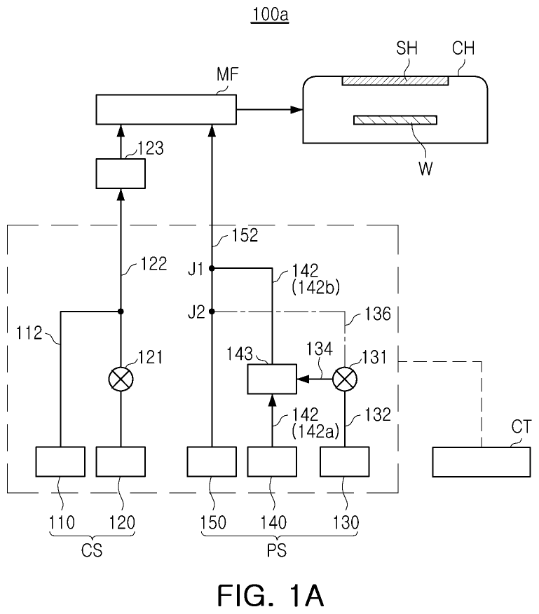

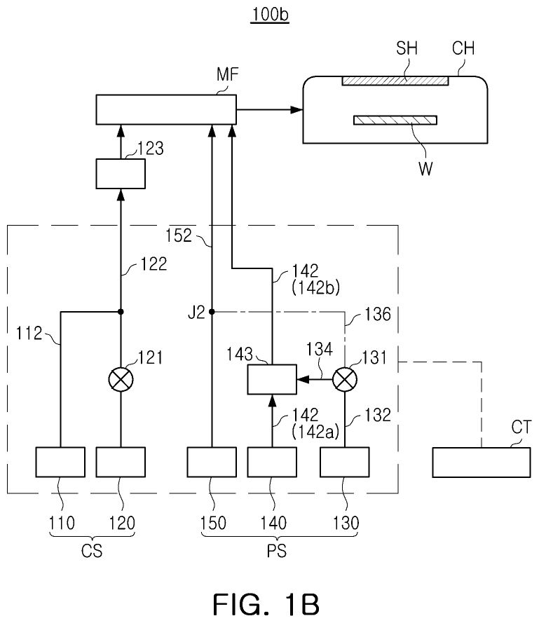

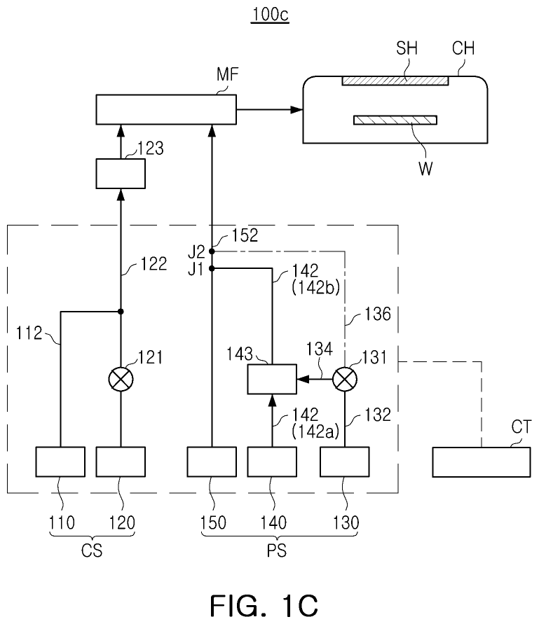

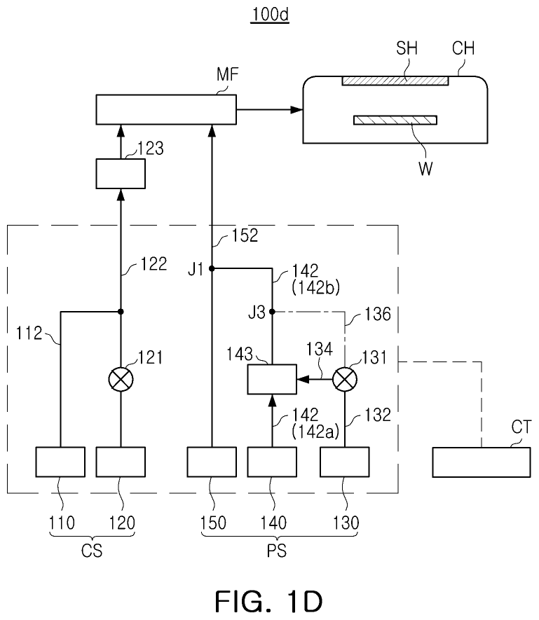

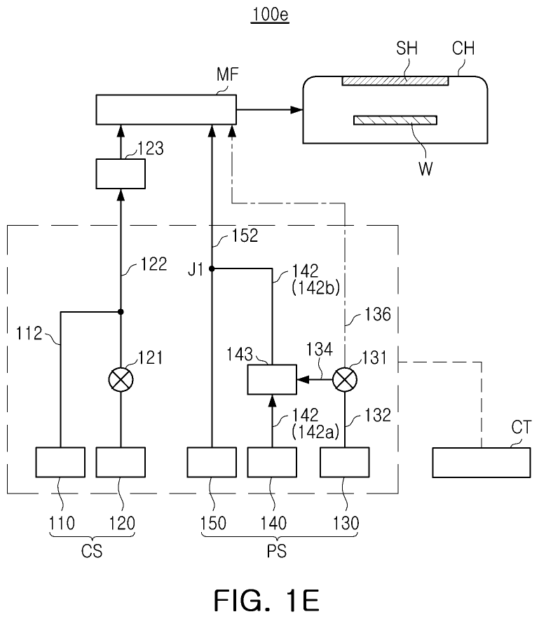

FIGS. 1A, 1B, 1C, 1D, and 1E are diagrams schematically illustrating gas supply systems according to example embodiments.

Referring to FIGS. 1A, 1B, 1C, 1D, and 1E, each of a gas supply system 100a, gas supply system 100b, a gas supply system 100c, a gas supply system 100d, and a gas supply system 100e of embodiments may include a cleaning gas supply unit CS, a process gas supply unit PS, and a controller CT controlling the cleaning gas supply unit CS and the process gas supply unit PS to provide gases for a process chamber CH. In addition, each of the gas supply system 100a, the gas supply system 100b, the gas supply system 100c, the gas supply system 100d, and the gas supply system 100e may further include a manifold MF through which gases are delivered from the cleaning gas supply unit CS and the process gas supply unit PS, and the process chamber CH to which gases which have passed through the manifold MF are supplied.

The process chamber CH may provide a processing space for a substrate W. The process chamber CH may constitute a deposition device configured to perform a deposition process on the substrate W using the gases supplied through the manifold MF. A shower head SH may be disposed in the process chamber CH. The shower head SH may spray gases supplied through the manifold MF into the processing space of the substrate W. The substrate W may be, for example, a silicon wafer used for manufacturing semiconductor devices, such as semiconductor integrated circuits (ICs). A stage on which the substrate W is seated may be disposed in the process chamber CH.

The manifold MF may be configured to separate or appropriately mix the gases provided from the cleaning gas supply unit CS and the process gas supply unit PS and supply the same to the process chamber CH. According to comparative embodiments, by-products may be generated by a reaction of heterogeneous gases in the manifold MF, and the manifold MF and the process chamber CH may be contaminated. According to embodiments, contamination of the manifold MF and the process chamber CH may be reduced and the process yield may be improved by preventing the gases causing a by-product occurrence in the manifold MF from being mixed.

The cleaning gas supply unit CS may include a cleaning gas source 120 and a cleaning gas supply line 122.

The cleaning gas source 120 may provide a cleaning gas for cleaning foreign substances generated during processing of the substrate W. The cleaning gas may include, for example, nitrogen trifluoride (NF₃), but is not limited thereto.

The cleaning gas supply line 122 may supply a cleaning gas provided from the cleaning gas source 120 to the manifold MF. A remote plasma source (RPS) 123 for converting the cleaning gas provided from the cleaning gas source 120 into plasma may be installed in the cleaning gas supply line 122, but is not limited thereto.

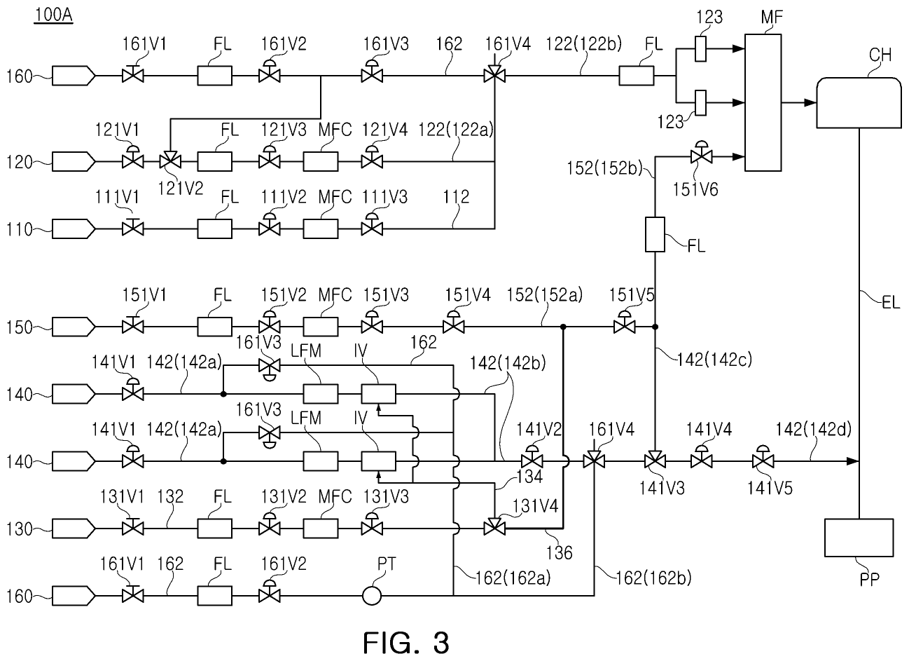

Elements for controlling gas flow, such as a valve, a filter, a mass flow controller (MFC), and the like, may be installed in the cleaning gas supply line 122 (refer to FIG. 3). For example, a first opening/closing valve 121 configured to open or close the cleaning gas supply line 122 may be installed between the RPS 123 and the cleaning gas source 120. For example, the first opening/closing valve 121 may be a two-way valve configured to open or close the cleaning gas supply line 122 to control cleaning gas flowing into the RPS 123.

According to example embodiments, the cleaning gas supply unit CS may further include a first inert gas source 110 and a first inert gas supply line 112.

The first inert gas source 110 may provide at least one of inert gases, such as helium (He), neon (Ne), argon (Ar), krypton (Kr), and xenon (Xe), to be mixed with the cleaning gas and supplied to the manifold MF.

The first inert gas supply line 112 may connect the first inert gas source 110 to the cleaning gas supply line 122. The first inert gas introduced into the cleaning gas supply line 122 through the first inert gas supply line 112 may be mixed with the cleaning gas and supplied to the manifold MF. Elements for controlling flow of gas, such as a valve, a filter, and a mass flow controller (MFC), may be installed in the first inert gas supply line 112 (refer to FIG. 3).

The process gas supply unit PS may include a source gas source 140, a source gas supply line 142, a reaction gas source 150, and a reaction gas supply line 152.

The source gas source 140 may provide a source material that participates in a chemical reaction for processing the substrate W. The source material may include, for example, at least one from among tetraethylorthosilicate (TEOS), triethyl borate (TEB), and triethyl phosphate (TEPO), but is not limited thereto.

The source gas supply line 142 may be configured to supply the source material provided from the source gas source 140 to the manifold MF. A vaporizer 143 may be installed in the source gas supply line 142 to vaporize a source material in a liquid state into source gas. According to an embodiment, the source gas supply line 142 may be connected to the reaction gas supply line 152 so that the source gas generated by the vaporizer 143 is supplied to the manifold MF through the reaction gas supply line 152. For example, the source gas supply line 142 may include a first source gas supply line 142a drawn from the source gas source 140 and connected to the vaporizer 143, and a second source gas supply line 142b drawn from the vaporizer 143 and connected to the reaction gas supply line 152.

Elements for controlling flow of gas, such as a valve, a filter, an MFC, a liquid flow meter (LFM), and the like may be installed in the source gas supply line 142 (refer to FIG. 3). For example, an LFM for measuring flow of the source material provided from the source gas source 140 may be installed in the first source gas supply line 142a, and an MFC may not be installed in the second source gas supply line 142b, but is not limited thereto.

The reaction gas source 150 may provide a reaction gas that participates in a chemical reaction for processing the substrate W. The reaction gas may include at least one from among oxygen (O₂), carbon dioxide (CO₂), and nitrous oxide (N₂O), but is not limited thereto. The reaction gas may be converted into plasma by a capacitively coupled plasma (CCP), an inductively coupled plasma (ICP), a remote plasma source (RPS), or the like, and applied to the substrate W treatment.

The reaction gas supply line 152 may be configured to supply the reaction gas provided from the reaction gas source 150 to the manifold MF. According to an embodiment, the reaction gas supply line 152 may be drawn from the reaction gas source 150 and directly connected to the manifold MF, but is not limited thereto. Elements for controlling the flow of gas, such as a valve, a filter, an MFC, and the like, may be installed in the reaction gas supply line 152 (refer to FIG. 3).

In example embodiments, the process gas supply unit PS may further include a second inert gas source 130 and a second inert gas supply line 132.

The second inert gas source 130 may provide an inert gas, for example, at least one from among helium (He), neon (Ne), argon (Ar), krypton (Kr), and xenon (Xe), for transporting a source gas (‘carrier gas’) and preventing backflow of the cleaning gas (“curtain gas”).

The second inert gas supply line 132 may be configured to supply a second inert gas provided from the second inert gas source 130 to the manifold MF. In example embodiments, the second inert gas supply line 132 may branch out to a carrier gas supply line 134 and a curtain gas supply line 136.

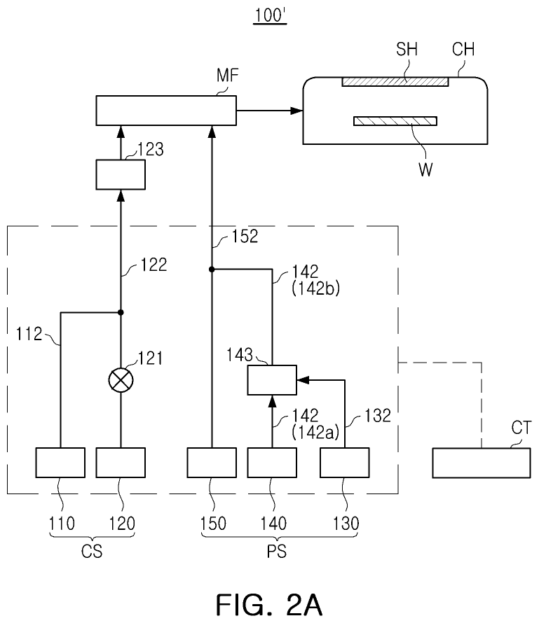

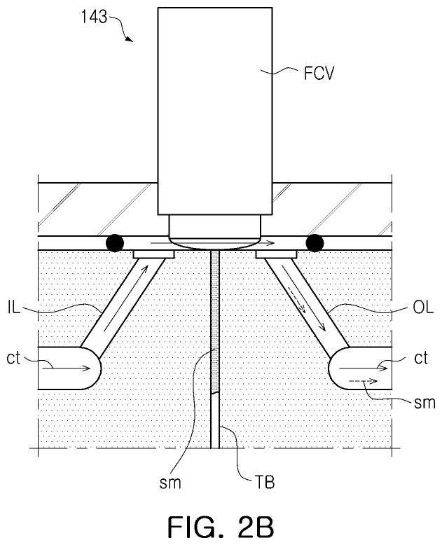

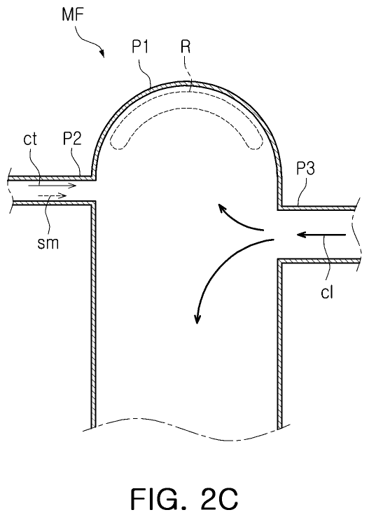

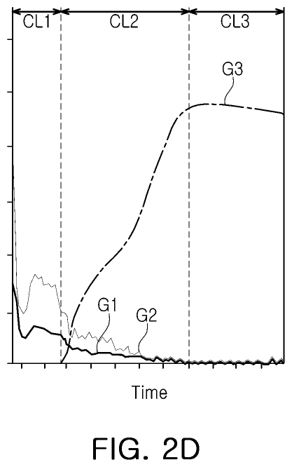

The carrier gas supply line 134 may branch off from the second inert gas supply line 132 and may be connected to the vaporizer 143. The carrier gas supply line 134 may be connected to an injection valve (e.g., refer to FIG. 2B) of the vaporizer 143 so that the second inert gas may join the source gas via the vaporizer 143. Accordingly, the second inert gas passing through the vaporizer 143 by the carrier gas supply line 134 may be supplied to the manifold MF together with the source gas through the source gas supply line 142.

The curtain gas supply line 136 may branch off from the second inert gas supply line 132 to bypass the vaporizer 143. The curtain gas supply line 136 may be configured such that the second inert gas bypasses the vaporizer 143 and is supplied to the manifold MF. For example, the curtain gas supply line 136 may be independently connected to the manifold MF or may be connected to the manifold MF through at least one from among the reaction gas supply line 152 and the source gas supply line 142. The second inert gas is supplied to the manifold MF by the curtain gas supply line 136 without leakage of the source material or the source gas remaining in the vaporizer 143, to prevent a reaction between the cleaning gas and the source gas and backflow of the cleaning gas. This will be described in detail with reference to FIGS. 2A to 2D.

Elements for controlling flow of gas, such as a valve, a filter, an MFC, and the like, may be installed in the second inert gas supply line 132 (refer to FIG. 3). In addition, a second opening/closing valve 131 configured to selectively open or close the carrier gas supply line 134 and the curtain gas supply line 136 may be installed at a branch point between the carrier gas supply line 134 and the curtain gas supply line 136. The second opening/closing valve 131 may be a three-way valve configured to selectively open or close the carrier gas supply line 134 and the curtain gas supply line 136. That is, when the carrier gas supply line 134 is opened, the curtain gas supply line 136 may be closed. Conversely, when the carrier gas supply line 134 is closed, the curtain gas supply line 136 may be opened.

As shown in FIG. 1A, in the gas supply system 100a of an embodiment, the source gas supply line 142 and the curtain gas supply line 136 may be connected to the reaction gas supply line 152 so that the source gas and the curtain gas (the second inert gas) may be supplied to the manifold MF. The source gas supply line 142 may be connected to the reaction gas supply line 152 at a first junction J1, and the curtain gas supply line 136 may be connected to the reaction gas supply line 152 at a second junction J2. The second junction J2 may be located between the first junction J1 and the reaction gas source 150, but is not limited thereto. According to example embodiments, the source gas supply line 142 and the curtain gas supply line 136 may be connected to the manifold MF through a path different from the path shown in FIG. 1A.

As shown in FIG. 1B, in the gas supply system 100b of an embodiment, the source gas supply line 142 may be directly connected to the manifold MF, so that the source gas may be directly supplied to the manifold MF. The curtain gas supply line 136 may be connected to the reaction gas supply line 152, so that the curtain gas (the second inert gas) may be supplied to the manifold MF.

As shown in FIG. 1C, in the gas supply system 100c of an embodiment, the source gas supply line 142 and the curtain gas supply line 136 may be connected to the reaction gas supply line 152, so that the source gas and the curtain gas (the second inert gas) may be supplied to the manifold MF. The source gas supply line 142 may be connected to the reaction gas supply line 152 at the first junction J1, the curtain gas supply line 136 may be connected to the reaction gas supply line 152 at the second junction J2, and the first junction J1 may be located between the second junction J2 and the reaction gas source 150, but is not limited thereto.

As shown in FIG. 1D, in the gas supply system 100d of an embodiment, the source gas supply line 142 may be connected to the reaction gas supply line 152 so that the source gas is supplied to the manifold MF. The curtain gas supply line 136 may be connected to the source gas supply line 142 so that the curtain gas (a second inert gas) may be supplied to the manifold MF. The source gas supply line 142 may be connected to the reaction gas supply line 152 at the first junction J1, and the curtain gas supply line 136 may be connected to the source gas supply line 142 at a third junction J3. The third junction J3 may be located between the vaporizer 143 and the first junction J1.

As shown in FIG. 1E, in the gas supply system 100e of an embodiment, the source gas supply line 142 may be connected to the reaction gas supply line 152 so that the source gas may be supplied to the manifold MF. The curtain gas supply line 136 may be directly connected to the manifold MF so that the curtain gas (the second inert gas) may be directly supplied to the manifold MF.

As described above, a bypass path of the curtain gas supply line 136 is not particularly limited and may be variously modified. According to embodiments, the curtain gas supply line 136 may be opened and closed together with the cleaning gas supply line 122 by the controller CT.

The controller CT may be configured to open or close the cleaning gas supply line 122, the reaction gas supply line 152, the source gas supply line 142, the carrier gas supply line 134, and the curtain gas supply line 136. The controller CT may be configured to simultaneously open or close the cleaning gas supply line 122 and the curtain gas supply line 136 by interlocking the first opening/closing valve 121 and the second opening/closing valve 131. For example, the controller CT may be configured to close the reaction gas supply line 152, the source gas supply line 142, and the carrier gas supply line 134 and open the cleaning gas supply line 122 when the curtain gas supply line 136 is opened.

Here, closing the reaction gas supply line 152, the source gas supply line 142, and the carrier gas supply line 134 does not mean completely cutting off the movement of fluid in each supply line, but rather may mean stopping gas supply from a gas source connected to each supply line. That is, even when the reaction gas supply line 152 is cut off, the curtain gas (the second inert gas) may be supplied to the manifold MF through the reaction gas supply line 152 connected to the curtain gas supply line 136.

The controller CT may include various devices for controlling the gas supply system. For example, the controller CT may include a storage device, a processor device, an analog and/or digital input/output device, and the like. The processor device may include, for example, a central processing unit (CPU), an application specific integrated circuit (ASIC), and the like. According to embodiments, the controller CT may include at least one processor and memory storing computer instructions. The computer instructions, when executed by the at least one processor, may be configured to cause the controller CT to perform its functions.

FIG. 2A is a diagram schematically illustrating a gas supply system 100′ according to Comparative Example, FIGS. 2B and 2C are views illustrating a process in which a by-product occurs due to leakage of a source material; and FIG. 2D is a graph illustrating the amount of leakage of a source material and the amount of generation of a by-product in a cleaning process.

Referring to FIG. 2A, the gas supply system 100′ of a Comparative Example may be understood as having a configuration similar to configurations of the gas supply system 100a, the gas supply system 100b, the gas supply system 100c, the gas supply system 100d, and the gas supply system 100e of embodiments of the present disclosure, except that the second inert gas supply line 132 does not branch off and is directly connected to the vaporizer 143.

In processing the substrate W, the second inert gas may transport the source material (‘source gas’) vaporized in the vaporizer 143 to the manifold MF and the process chamber CH. For example, the second inert gas provided from the second inert gas source 130 may join the source gas in the vaporizer 143 through the second inert gas supply line 132, and then the source gas may be transported to the manifold MF.

In cleaning the process chamber CH, the second inert gas may prevent the cleaning gas from flowing backward in the manifold MF. For example, the second inert gas provided from the second inert gas source 130 may be a curtain gas and may be supplied up to the manifold MF through the second inert gas supply line 132, the source gas supply line 142, and the reaction gas supply line 152. The supply of the source gas from the source gas source 140 and the supply of the reaction gas from the reaction gas source 150 may be stopped. In the gas supply system 100′ of the Comparative Example, the second inert gas (or “curtain gas”) may be supplied to the manifold MF through a path passing through the vaporizer 143. In this case, the source material remaining in the vaporizer 143 may leak due to the curtain gas and react with a cleaning gas in the manifold MF to form by-products.

Referring to FIG. 2B, in the cleaning of the process chamber CH, a flow control valve (FCV) of the vaporizer 143 may block a tube TB connected to the source gas source 140 to cut off supply of a source material sm. The curtain gas ct may pass through the vaporizer 143 along an inlet pipe IL and an outlet pipe OL of a carrier gas. At this time, the source material sm remaining in the tube TB may leak into the outlet pipe OL together with the curtain gas ct. The source material sm may be in a liquid or gaseous state.

Referring to FIG. 2C, in cleaning the process chamber CH, the cleaning gas cl may flow into a first pipe P1 connected to the process chamber CH through a third pipe P3. The curtain gas ct may be supplied to a second pipe P2 to block the cleaning gas cl from entering the second pipe P2 connected to the first pipe P1. At this time, the source material sm (e.g., TEOS) leaked by the curtain gas ct may react with the cleaning gas cl (e.g., NF₃) in a region R adjacent to the second pipe P2 to produce by-products (e.g., CH₃F). By-products generated in the first pipe P1 connected to the process chamber CH may cause contamination of the manifold MF and the process chamber CH and reduce process yield. Table 1 below illustrates the results of scanning electron microscope-energy dispersive spectroscopy (SEM-EDS) analysis of by-products generated in the region R. Referring to Table 1, it can be seen that by-products (e.g., solid particles) generated in the first pipe P1 include about 85 wt % or more of carbon (C) and fluorine (F) and about 15 wt % or less of oxygen (O) and silicon (Si). That is, it can be seen that the by-products generated in the region R are generated as the materials (e.g., oxygen (O), carbon (C), and silicon (Si)) constituting the source material sm (e.g., TEOS) react with the material (e.g., fluorine (F)) constituting the cleaning gas cl.

TABLE 1

| Element | | C | O | F | Si |
|---|---|---|---|---|---|
| Mass [%] | First specimen | 35.7 | 8.84 | 55.02 | 0.6 |
| | Second specimen | 46.34 | 11.28 | 40.19 | 2.18 |

Referring to FIG. 2D, the leakage amount of the source material sm (e.g., TEOS) for each cleaning operation CL1, CL2, and CL3 of the process chamber CH may be known. A first operation CL1 is an operation in which the curtain gas ct is supplied, a second operation CL2 is an operation in which the cleaning gas cl is supplied, and a third operation CL3 is an operation in which a cleaning process is performed with the cleaning gas cl. A first graph G1 indicates a detection amount of the source material sm in the cleaning process of an embodiment of the embodiment of the present disclosure. A second graph G2 indicates a detection amount of the source material sm in the cleaning process of the Comparative Example. A third graph G3 indicates a detection amount of the cleaning gas cl (e.g., a detection amount of F₂). The source material sm and the cleaning gas cl were detected through a residual gas analyzer (RGA) installed in a vacuum pipe (refer to vacuum pipe EL in FIG. 3) connected to the process chamber CH.

Referring to the second graph G2 and the third graph G3, it can be seen that the source material sm (e.g., TEOS) leaked by the curtain gas ct and the cleaning gas cl (e.g., NF₃) coexists in the process chamber CH in the second operation CL2. That is, in the second operation CL2, the source material sm (e.g., TEOS) and the cleaning gas cl (e.g., NF₃) may react with each other to produce by-products (e.g., CH₃F).

Meanwhile, referring to the first graph G1, in the case of an embodiment in which the curtain gas supply line bypasses the vaporizer, it can be seen that the leakage amount of the source material sm coexisting with the cleaning gas cl in the second operation CL2 is relatively reduced. That is, according to example embodiments, it can be easily understood that the reaction between the cleaning gas cl (e.g., NF₃) and the source material sm is reduced and generation of by-product is suppressed.

FIG. 3 is a diagram illustrating a gas supply system 100A according to an example embodiment.

Referring to FIG. 3, the gas supply system 100A may include a first inert gas source 110, a cleaning gas source 120, a second inert gas source 130, a source gas source 140, and a reaction gas source 150 configured to supply gases to the manifold MF and the process chamber CH. Gases may be supplied to the process chamber CH through the manifold MF. The process chamber CH may be connected to a vacuum pump PP through a vacuum pipe EL for internal gas discharge.

The first inert gas source 110 may provide inert gases, for example, at least one from among helium (He), neon (Ne), argon (Ar), krypton (Kr), and xenon (Xe) to be mixed with the cleaning gas and supplied to the manifold MF. The first inert gas may be supplied to the manifold MF through the first inert gas supply line 112. The first inert gas supply line 112 may be connected to the cleaning gas supply line 122. The first inert gas may transport the cleaning gas in the cleaning gas supply line 122 and reach the manifold MF. Elements for controlling flow of the first inert gas, for example, valves 111V1, 111V2, and 111V3, a filter FL, and an MFC, may be installed in the first inert gas supply line 112.

The cleaning gas source 120 may provide a cleaning gas, such as, for example, nitrogen trifluoride (NF₃). The cleaning gas may be supplied to the manifold MF through the cleaning gas supply line 122. The cleaning gas supply line 122 may include a first cleaning gas supply line 122a through which the cleaning gas provided from the cleaning gas source 120 is circulated, and a second cleaning gas supply line 122b through which the cleaning gas is mixed with a first inert gas and circulated. Elements for controlling the flow of the cleaning gas, for example, valves 121V1, 121V2, 121V3, and 121V4, a filter FL, and an MFC, may be installed in the cleaning gas supply line 122. In addition, an RPS 123 for converting the cleaning gas into plasma may be installed in the cleaning gas supply line 122. In an embodiment, the valve 121V4 (e.g., a final valve) of the cleaning gas supply line 122 may interwork with a valve 131V4 (e.g., a branch valve) of the second inert gas supply line 132.

The second inert gas source 130 may provide inert gases used as a carrier gas and curtain gas, for example, at least one from among helium (He), neon (Ne), argon (Ar), krypton (Kr), and xenon (Xe). The second inert gas supply line 132 may branch out to the carrier gas supply line 134 and the curtain gas supply line 136. The carrier gas supply line 134 may be connected to an injection valve IV of the vaporizer installed in the source gas supply line 142. The curtain gas supply line 136 may bypass the injection valve IV (or the vaporizer) and be connected to the reaction gas supply line 152. Elements for controlling the flow of the second inert gas may include, for example, valves 131V1, 131V2, 131V3, and 131V4, a filter FL, and an MFC, in the second inert gas supply line 132, the carrier gas supply line 134, and the curtain gas supply line 136. The valve 131V4 installed at a branch point of the carrier gas supply line 134 and the curtain gas supply line 136 may interwork with the valve 121V4 (e.g., the final valve) of the cleaning gas supply line 122. For example, when the valve 131V4 operates (e.g., due to control of the controller CT) to open the curtain gas supply line 136, the valve 121V4 may operate (e.g., due to control of the controller CT) to open the cleaning gas supply line 122.

The source gas source 140 may provide, for example, a source material including at least one from among tetraethylorthosilicate (TEOS), triethyl borate (TEB), and triethyl phosphate (TEPO). A vaporizer (indicated as an injection valve IV) may be installed in the source gas supply line 142. The source gas supply line 142 may include a first source gas supply line 142a drawn from the source gas source 140 and connected to the injection valve IV, and a second source gas supply line 142b drawn from the injection valve IV and connected to the reaction gas supply line 152. According to an embodiment, the second source gas supply line 142b may branch out to a third source gas supply line 142c joining the reaction gas supply line 152 and a fourth source gas supply line 142d connected to the vacuum pipe EL. Elements for controlling gas flow, for example, valves 141V1, 141V2, 141 V3, 141V4, and 141V5, a filter FL, and an LFM may be installed in the source gas supply line 142.

The reaction gas source 150 may provide a reaction gas including at least one from among oxygen (O₂), carbon dioxide (CO₂), and nitrous oxide (N₂O). The reaction gas supply line 152 may be drawn from the reaction gas source 150 and directly connected to the manifold MF. The reaction gas supply line 152 may include a first reaction gas supply line 152a at a front of a connection point of the source gas supply line 142, and a second reaction gas supply line 152b at a rear thereof. Elements for controlling the flow of gas, for example, valves 151V1, 151V2, 151 V3, 151V4, 151 V5, and 151V6, a filter FL, and an MFC may be installed in the reaction gas supply line 152.

According to embodiments, the gas supply system 100A may further include a purge gas source 160. The purge gas source 160 may provide a purge gas for removing excess gases and reaction by-products inside the process chamber CH. The purge gas supply line 162 may be connected to at least one from among the cleaning gas supply line 122, the reaction gas supply line 152, the source gas supply line 142, the first inert gas supply line 112, and the second inert gas supply line 132. Elements for controlling the flow of gas, for example, valves 161V1, 161V2, 161 V3, and 161V4, a filter FL, and a pressure sensor PT may be installed in the purge gas supply line 162.

FIG. 3 merely illustrates elements constituting the gas supply system 100A by way of example, and gas supply systems according to example embodiments are not limited thereto. Hereinafter, a movement path of the second inert gas through the carrier gas supply line 134 and the curtain gas supply line 136 will be described with reference to the gas supply system 100A of FIG. 3.

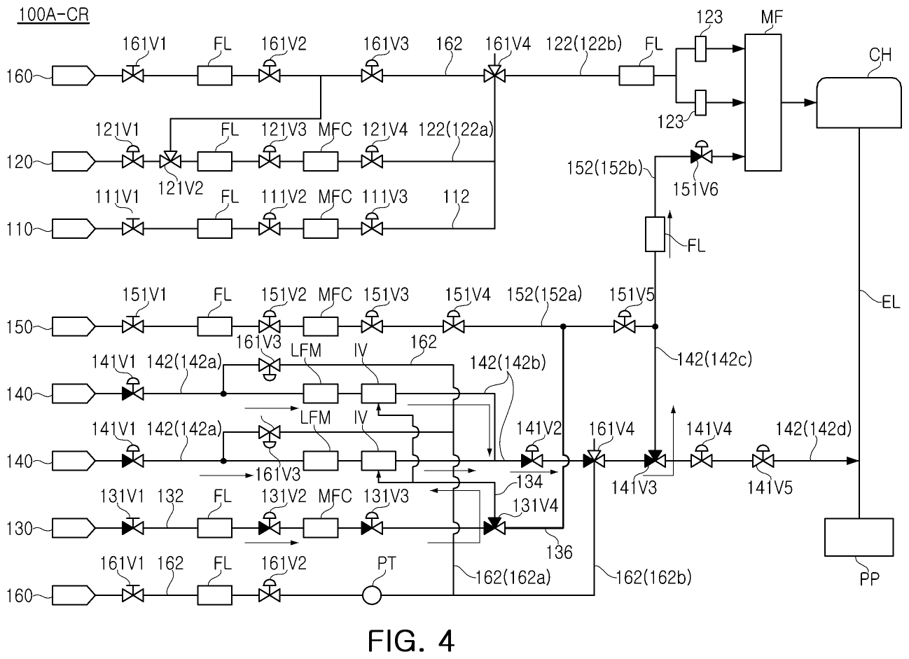

FIG. 4 is a diagram illustrating a gas supply system 100A-CR in which the carrier gas supply line 134 is open.

Referring to FIG. 4, a source material provided from the source gas source 140 may flow into the injection valve IV through the first source gas supply line 142a. A vaporized source material (“source gas”) passing through the injection valve IV may be supplied to the manifold MF through the second source gas supply line 142b and the reaction gas supply line 152. When the source gas supply line 142 is opened (e.g., due to control of the controller CT), the carrier gas supply line 134 may be opened by the valve 131V4 (e.g., due to control of the controller CT). The second inert gas provided from the second inert gas source 130 may flow into the injection valve IV through the carrier gas supply line 134 and be supplied to the manifold MF together with the source gas. The curtain gas supply line 136 may be closed by the valve 131V4 (e.g., due to control of the controller CT).

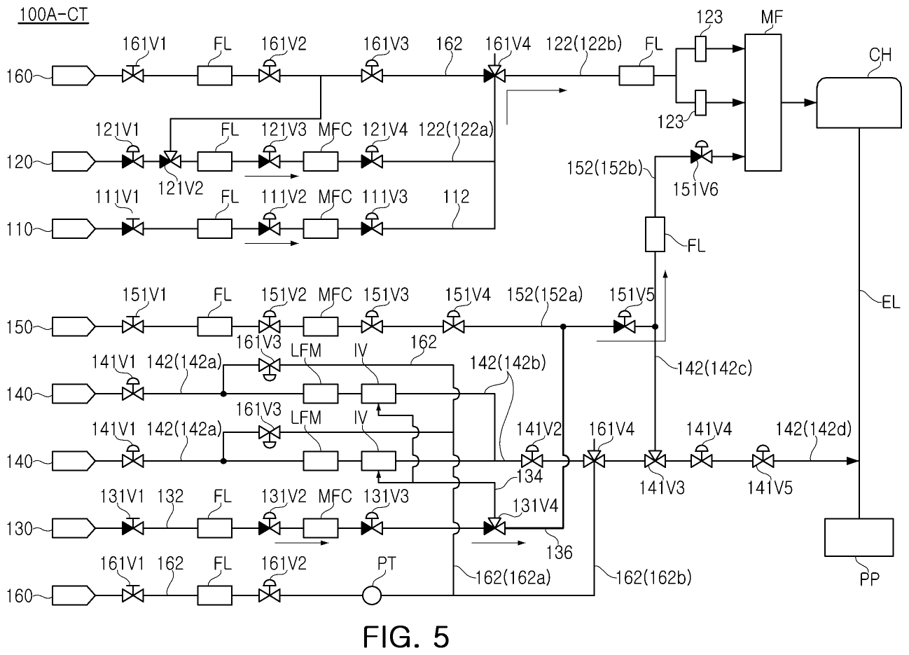

FIG. 5 is a diagram illustrating a gas supply system 100A-CT in which the curtain gas supply line 136 is opened.

Referring to FIG. 5, a cleaning gas provided from the cleaning gas source 120 may be supplied to the manifold MF through the cleaning gas supply line 122. The cleaning gas may be converted into plasma by the RPS 123 to be provided. The first inert gas provided from the first inert gas source 110 may join the cleaning gas supply line 122 through the first inert gas supply line 112 and be supplied to the manifold MF together with the cleaning gas. When the valve 121V4 of the cleaning gas supply line 122 is opened (e.g., due to control of the controller CT), the curtain gas supply line 136 may be opened by the valve 131V4 (e.g., due to control of the controller CT). The second inert gas provided from the second inert gas source 130 may bypass the injection valve IV through the curtain gas supply line 136 to be supplied to the manifold MF. The carrier gas supply line 134 may be closed by the valve 131V4 (e.g., due to control of the controller CT).

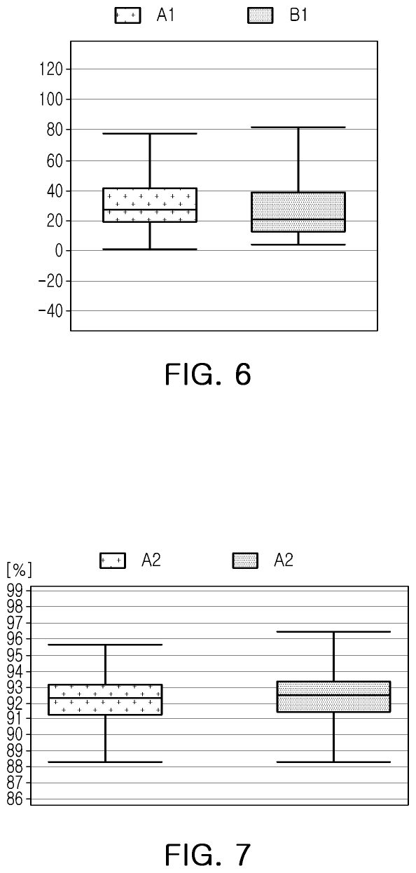

FIG. 6 is a graph illustrating a particle reduction effect in a process chamber after applying the gas supply system 100A according to an example embodiment.

Referring to FIG. 6, ‘A1’ represents an average value (about 41.4) of the number of particles inside the process chamber for a predetermined period in the gas supply system of the comparative example. ‘B1’ represents an average value (about 28.6) of the number of particles inside the process chamber for a predetermined period in the gas supply system 100A of the embodiment. It can be seen that the number of particles in the process chamber is reduced when the curtain gas is supplied by bypassing the vaporizer during cleaning of the process chamber.

FIG. 7 is a graph illustrating a yield improvement effect after applying a gas supply system 100A according to an embodiment.

Referring to FIG. 7, ‘A2’ represents an average value (about 92.017%) of a substrate processing yield for a predetermined period in the gas supply system of the comparative example. ‘B2’ represents an average value (about 92.047%) of the substrate processing yield for a predetermined period in the gas supply system 100A of the embodiment. It can be seen that the substrate processing yield is improved when the curtain gas is supplied by bypassing the vaporizer during cleaning of the process chamber.

According to example embodiments, the gas supply system in which the occurrence of by-products is prevented by introducing the curtain gas supply line that opens and closes in conjunction with the cleaning gas supply line may be provided.

While example embodiments have been shown and described above, it will be apparent to those skilled in the art that modifications and variations could be made without departing from the scope of the present disclosure.

What is claimed is:

1. A gas supply system comprising:
a process chamber configured to receive a substrate;
a manifold configured to supply gases for processing the substrate to the process chamber;
a cleaning gas supply line configured to supply a cleaning gas provided from a cleaning gas source to the manifold;
a first inert gas supply line configured to supply a first inert gas provided from a first inert gas source to the cleaning gas supply line;
a first opening/closing valve in the cleaning gas supply line and configured to open and close the cleaning gas supply line;
a reaction gas supply line configured to supply a reaction gas provided from a reaction gas source to the manifold;
a source gas supply line configured to supply a source gas to the manifold;
a vaporizer that is in the source gas supply line and configured to vaporize a source material provided from a source gas source into the source gas;
a second inert gas supply line configured to supply a second inert gas provided from a second inert gas source to the manifold, the second inert gas supply line branching out to a carrier gas supply line that is connected to the vaporizer and a curtain gas supply line that bypasses the vaporizer;
a second opening/closing valve that is at a branch point of the second inert gas supply line and is configured to selectively open or close the carrier gas supply line and the curtain gas supply line; and
a controller configured to simultaneously open or close the cleaning gas supply line and the curtain gas supply line by interlocking the first opening/closing valve and the second opening/closing valve.

2. The gas supply system of claim 1, wherein the first opening/closing valve is a two-way valve, and the second opening/closing valve is a three-way valve.

3. The gas supply system of claim 1, wherein the carrier gas supply line is connected to an injection valve of the vaporizer.

4. The gas supply system of claim 1, wherein the curtain gas supply line is connected to at least one from among the reaction gas supply line and the source gas supply line.

5. The gas supply system of claim 1, wherein the first inert gas and the second inert gas comprise at least one from among helium (He), neon (Ne), argon (Ar), krypton (Kr), and xenon (Xe).

6. The gas supply system of claim 1, wherein the source material comprises at least one from among tetraethylorthosilicate (TEOS), triethyl borate (TEB), and triethyl phosphate (TEPO).

7. The gas supply system of claim 1, wherein the source gas supply line comprises:
a first source gas supply line that extends from the source gas source and is connected to the vaporizer; and
a second source gas supply line that extends from the vaporizer.

8. The gas supply system of claim 7, further comprising a liquid flow meter (LFM) in the first source gas supply line.

9. The gas supply system of claim 1, wherein the cleaning gas comprises nitrogen trifluoride (NF₃).

10. The gas supply system of claim 1, further comprising a remote plasma source (RPS) in the cleaning gas supply line.

11. The gas supply system of claim 1, wherein the reaction gas comprises at least one from among oxygen (O₂), carbon dioxide (CO₂), and nitrous oxide (N₂O).

12. The gas supply system of claim 1, further comprising respective mass flow controllers (MFCs) in each of the first inert gas supply line, the second inert gas supply line, the cleaning gas supply line, and the reaction gas supply line.

13. The gas supply system of claim 1, wherein
the reaction gas supply line extends from the reaction gas source and is directly connected to the manifold,
the source gas supply line is connected to the reaction gas supply line at a first junction, and
the curtain gas supply line is connected to the reaction gas supply line at a second junction.

14. The gas supply system of claim 13, wherein the second junction is located between the first junction and the reaction gas source.

15. The gas supply system of claim 1, further comprising a purge gas supply line configured to supply a purge gas provided from a purge gas source to at least one from among the cleaning gas supply line, the reaction gas supply line, the source gas supply line, the first inert gas supply line, and the second inert gas supply line.

16. A gas supply system comprising:
a process chamber configured to receive a substrate;
a manifold configured to supply gases for processing the substrate to the process chamber;
a cleaning gas supply line configured to supply a cleaning gas provided from a cleaning gas source to the manifold;
a remote plasma source (RPS) in the cleaning gas supply line and configured to convert the cleaning gas into plasma;
a reaction gas supply line configured to supply a reaction gas provided from a reaction gas source to the manifold;
a source gas supply line configured to supply a source gas to the manifold;
a vaporizer in the source gas supply line and configured to vaporize a source material provided from a source gas source into the source gas;
an inert gas supply line configured to supply an inert gas provided from an inert gas source to the manifold;
a carrier gas supply line branching off from the inert gas supply line and connected to the vaporizer so that the inert gas is provided to the manifold via the vaporizer;
a curtain gas supply line branching off from the inert gas supply line and connected to the reaction gas supply line, the source gas supply line, or the manifold so that the inert gas bypasses the vaporizer to be provided to the manifold; and
a controller configured to open and close the cleaning gas supply line, the reaction gas supply line, the source gas supply line, the carrier gas supply line, and the curtain gas supply line.

17. The gas supply system of claim 16, wherein the inert gas passing through the vaporizer by the carrier gas supply line is provided to the manifold together with the source gas through the source gas supply line.

18. The gas supply system of claim 16, wherein the inert gas bypassing the vaporizer by the curtain gas supply line is provided to the manifold through the reaction gas supply line or the source gas supply line or is directly supplied to the manifold.

19. The gas supply system of claim 16, wherein the controller is configured to, when the curtain gas supply line is opened, close the reaction gas supply line, the source gas supply line, and the carrier gas supply line, and open the cleaning gas supply line.

20. A gas supply system comprising:
a manifold configured to supply gases for processing a substrate to a process chamber;
a cleaning gas supply line configured to supply a cleaning gas provided from a cleaning gas source to the manifold;
a remote plasma source (RPS) in the cleaning gas supply line and configured to convert the cleaning gas into plasma;
a reaction gas supply line configured to supply a reaction gas provided from a reaction gas source to the manifold;
a source gas supply line connected to the reaction gas supply line so that a source gas is supplied to the manifold through the reaction gas supply line;
a vaporizer in the source gas supply line and configured to vaporize a source material provided from a source gas source into the source gas;
an inert gas supply line branching out to:
a carrier gas supply line connected to the vaporizer so that an inert gas provided from an inert gas source joins the source gas via the vaporizer, and
a curtain gas supply line connected to the reaction gas supply line so that the inert gas bypasses the vaporizer to be provided to the manifold; and
a controller configured to, when the cleaning gas supply line is opened, open the curtain gas supply line and close the carrier gas supply line.
